(19) United States
(12) Patent Application Publication
(10) Pub. No.: US 2025/0309076 A1
(43) Pub. Date: Oct. 2, 2025

(54) SUBSTRATE WITH EMBEDDED ELECTRONIC COMPONENT AND METHOD OF MAKING THE SAME

(71) Applicant: SHINKO ELECTRIC INDUSTRIES CO., LTD., Nagano (JP)

(72) Inventors: Shinichiro SEKIJIMA, Nagano (JP); Kenkichi ARAI, Nagano (JP); Satoshi MATSUZAWA, Nagano (JP); Masataka KAZAMA, Nagano (JP)

(21) Appl. No.: 19/088,023

(22) Filed: Mar. 24, 2025

(30) Foreign Application Priority Data
Mar. 28, 2024 (JP) 2024-053406

(51) Int. Cl. H01L 23/498; H01L 23/31

(52) U.S. Cl. CPC H01L 23/49816; H01L 23/3135; H01L 23/49833; H01L 23/49838

(57) ABSTRACT

A substrate with an embedded electronic component includes a first substrate, a second substrate on which an electronic component is mounted, connecting member electrically and a substrate connecting a first pad of the first substrate and a second pad of the second substrate, wherein the first substrate is disposed opposite the second substrate across the electronic component, wherein the substrate connecting member includes a first core in contact with the first pad, a second core in contact with the first core and the second pad, and a conductive member covering the first core and the second core, and in contact with the first pad and the second pad, and wherein the first core and the second core are spherical, and a diameter of the second core is smaller than a diameter of the first core.

### CROSS-REFERENCE TO RELATED APPLICATIONS

The present application is based on and claims priority to Japanese Patent Application No. 2024-053406 filed on Mar. 28, 2024, with the Japanese Patent Office, the entire contents of which are incorporated herein by reference.

### FIELD

The disclosures herein relate to substrates with an embedded electronic component and methods of manufacturing such a substrate.

### BACKGROUND

A substrate with an embedded electronic component as known in the art may include a first substrate, a second substrate facing the first substrate, substrate connecting members interposed between the first substrate and the second substrate to transmit signals between the first substrate and the second substrate, and an encapsulating resin for encapsulating the gap between the first substrate and the second substrate with the substrate connecting members intervening therebetween, with an electronic component such as a semiconductor chip mounted on the second substrate (See, for example, Patent Document 1).

With respect to the substrate with an embedded electronic component as described above, an increase of the thickness of electronic component requires an increase in the widths of the substrate connecting members, which results in the substrate with an embedded electronic component becoming larger in the width direction.

There may be a need to provide a substrate with an embedded electronic component that is unlikely to be enlarged in the width direction even when the thickness of the electronic component is increased.

### PRIOR ART DOCUMENTS

### Patent Documents

[Patent Document 1] International Publication Pamphlet No. WO2007/069606

### SUMMARY

According to an aspect of the embodiment, a substrate with an embedded electronic component includes a first substrate, a second substrate on which an electronic component is mounted, and a substrate connecting member electrically connecting a first pad of the first substrate and a second pad of the second substrate, wherein the first substrate is disposed opposite the second substrate across the electronic component, wherein the substrate connecting member includes a first core in contact with the first pad, a second core in contact with the first core and the second pad, and a conductive member covering the first core and the second core, and in contact with the first pad and the second pad, and wherein the first core and the second core are spherical, and a diameter of the second core is smaller than a diameter of the first core.

The object and advantages of the embodiment will be realized and attained by means of the elements and combinations particularly pointed out in the claims. It is to be understood that both the foregoing general description and following detailed description are exemplary and explanatory and are not restrictive of the invention, as claimed.

### BRIEF DESCRIPTION OF DRAWINGS

FIG. 1 is a cross-sectional views illustrating an example of a substrate with an embedded electronic component according to a first embodiment;

FIGS. 2A through 2C are drawings illustrating an example of a manufacturing process of the substrate with an embedded electronic component according to the first embodiment;

FIGS. 3A and 3B are drawings illustrating the example of the manufacturing process of the an embedded electronic component substrate with according to the first embodiment; and ed electronic component according to the first embodiment; and

FIG. 4 is a cross-sectional view illustrating an example of a substrate with an embedded electronic component according to a variation of the first embodiment.

### DESCRIPTION OF EMBODIMENTS

In the following, an embodiment for carrying out the invention will be described with reference to the accompanying drawings. In each of the drawings, the same components are referred to by the same reference numerals, and duplicate descriptions may be omitted.

### First Embodiment

### Structure of Substrate with Embedded Electronic Component

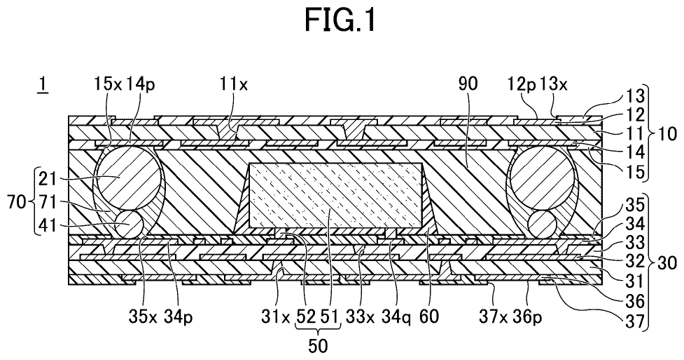

FIG. 1 is a cross-sectional views illustrating an example of a substrate with an embedded electronic component according to a first embodiment.

Referring to FIG. 1, a substrate 1 with an embedded electronic component includes a first substrate 10, a second substrate 30, a semiconductor chip 50, substrate connecting members 70, and an encapsulating resin 90. In the substrate 1 with an embedded electronic component, the semiconductor chip 50 is mounted on the second substrate 30, and the first substrate 10 is arranged opposite the second substrate 30 across the semiconductor chip 50. The encapsulating resin 90 fills the gap between the first substrate 10 and the second substrate 30 to cover the semiconductor chip 50.

In the present embodiment, for the sake of convenience, the solder resist layer 13 side of the substrate 1 with an embedded electronic component in FIG. 1 is referred to as an upper side or a first side, and the solder resist layer 37 side is referred to as a lower side or a second side. In addition, the surface of an object oriented in the same direction as the solder resist layer 13 side is referred to as a first surface or an upper surface, and the surface of the object oriented in the same direction as the solder resist layer 37 side is referred to as a second surface or a lower surface. However, the substrate 1 with an embedded electronic component may be used upside down or may be arranged at any angle. The plan view refers to the view of an object as seen from the direction normal to the first surface of the solder resist layer 13, and the plane shape refers to the shape of an object as seen from the direction normal to the first surface of the solder resist layer 13. When the substrate 1 with an embedded electronic component is illustrated upside down relative to FIG. 1, the definition of the upper side and the lower side becomes opposite to that described above, in accordance with the orientation of the drawing.

The first substrate 10 includes an insulating layer 11, an interconnect layer 12, a solder resist layer 13, an interconnect layer 14, and a solder resist layer 15.

In the first substrate 10, the insulating layer 11 may be, for example, a glass epoxy substrate or the like in which an insulating resin, such as epoxy-based resin, is impregnated into a glass cloth. The insulating layer 11 may be a substrate or the like in which an insulating resin, such as epoxy-based resin, is impregnated into a woven fabric or a nonwoven fabric such as a glass fiber, carbon fiber or aramid fiber. The thickness of the insulating layer 11 may be, for example, about 60 to 200 μm. The illustration of the glass cloth or the like is omitted in each of the drawings.

The interconnect layer 12 is formed on the the first side of insulating layer 11. The interconnect layer 12 is electrically connected to the interconnect layer 14 through the insulating layer 11. The interconnect layer 12 includes at least one via interconnect filling a via hole 11x penetrating the insulating layer 11 and reaching the first surface of the interconnect layer 14, and also includes an interconnect pattern formed on the first surface of the insulating layer 11.

The via hole 11x is an inverted truncated conical recess in which the diameter of an opening towards the solder resist layer 13 is larger than the diameter of a bottom surface formed by the upper surface of the interconnect layer 14. The diameter of the opening of the via hole 11x may be, for example, about 50 μm. The material of the interconnect layer 12 may be, for example, copper (Cu) or the like. The thickness of the interconnect pattern of the interconnect layer 12 may be, for example, about 10 to 20 μm.

The solder resist layer 13 is formed on the first surface of the insulating layer 11 so as to cover the interconnect layer 12. The solder resist layer 13 may be, for example, made of photosensitive resin or the like. The thickness of the solder resist layer 13 may be, for example, about 15 to 35 μm. The solder resist layer 13 has at least one opening 13x, and a part of the interconnect layer 12 is exposed in the opening 13x. The interconnect layer 12 exposed in the opening 13x forms a pad 12p. The pad 12p serves to establish an electrical connection to an electronic component (not shown) such as a semiconductor chip or a semiconductor package.

The solder resist layer 13 may be configured to completely expose the pad 12p. In this case, the solder resist layer 13 may be provided so that the side surface of the pad 12p is in contact with the inner wall surface of the opening 13x, or the solder resist layer 13 may be provided so that there is a gap between the side surface of the pad 12p and the inner wall surface of the opening 13x.

According to need, a metal layer may be formed on the first surface of the pad 12p, or an antioxidation treatment such as OSP (organic solderability preservative) treatment may be applied. Examples of the metal layer include an Au layer, a Ni/Au layer (i.e., a metal layer made by laminating a Ni layer and an Au layer in this order), and a Ni/Pd/Au layer (i.e., a metal layer made by laminating a Ni layer, a Pd layer, and an Au layer in this order). An external connection terminal such as a solder ball may be formed on the first surface of the pad 12p.

The interconnect layer 14 is formed on the second surface of the insulating layer 11. The interconnect layer 14 includes, for example, a pad and an interconnect pattern provided on the same surface as the pad. The first surface of the interconnect layer 14 is in contact with, and electrically connected to, the lower end of the via interconnect of the interconnect layer 12 filling the via hole 11x. The material and thickness of the interconnect layer 14 may be, for example, substantially the same as those of the interconnect pattern of the interconnect layer 12.

The solder resist layer 15 is formed on the second surface of the insulating layer 11 so as to cover the interconnect layer 14. The material and thickness of the solder resist layer 15 may be, for example, substantially the same as those of the solder resist layer 13. The solder resist layer 15 has an opening 15x, and a part of the interconnect layer 14 is located in the opening 15x. The plane shape of the opening 15x may be, for example, circular. The interconnect layer 14 situated in the opening 15x constitutes a pad 14p. The pad 14p serves to establish an electrical connection to a substrate connecting member 70. If necessary, the second surface of the pad 14p may have the previously described metal layer formed thereon, or subjected to antioxidation treatment such as OSP treatment.

The second substrate 30 includes an insulating layer 31, an interconnect layer 32, an insulating layer 33, an interconnect layer 34, a solder resist layer 35, an interconnect layer 36, and a solder resist layer 37.

In the second substrate 30, the material and thickness of the insulating layer 31 may be substantially the same as those of the insulating layer 11, for example. The interconnect layer 32 is formed on the first surface of the insulating layer 31. The material and thickness of the interconnect layer 32 may be the same as those of the interconnect pattern of the interconnect layer 12, for example.

The insulating layer 33 is formed on the first surface of the insulating layer 31 so as to cover the interconnect layer 32. An insulating resin, such as a thermosetting epoxy-based resin, may be used as the material of the insulating layer 33. The insulating layer 33 may contain a filler such as silica (SiO₂). The thickness of the insulating layer 33 may be, for example, about 15 to 35 μm.

The interconnect layer 34 is formed on the first side of the insulating layer 33. The interconnect layer 34 includes at least one via interconnect filling a via hole 33x penetrating the insulating layer 33 and reaching the first surface of the interconnect layer 32, and also includes an interconnect pattern formed on the first surface of the insulating layer 33. The interconnect pattern of the second substrate 30 on which the semiconductor chip 50 is mounted is denser than the interconnect pattern of the first substrate 10.

The via hole 33x is an inverted truncated conical recess which has an opening toward the solder resist layer 35 and a bottom surface formed by the first surface of the interconnect layer 32, and the area of the opening is larger than the area of the bottom surface. The material of the interconnect layer 34 and the thickness of the interconnect pattern of the interconnect layer 34 may be, for example, the same as those of the interconnect layer 12.

The solder resist layer 35 is a protective insulating layer formed on the first surface of the insulating layer 33 so as to cover the interconnect layer 34. The material and thickness of the solder resist layer 35 may be substantially the same as those of the solder resist layer 13, for example. The solder resist layer 35 has at least one opening 35x, and a part of the interconnect layer 34 is located in the opening 35x. The plane shape of the opening 35x may be circular, for example. The interconnect layer 34 situated in the opening 35x serves as pads 34p and 34q.

The pad 34p serves to establish a connection to a substrate connecting member 70. The pad 34q serves to establish a connection to an electrode 52 of the semiconductor chip 50. A plurality of pads 34p and a plurality of pads 34q are formed on the semiconductor chip 50 side of the second substrate 30. The pads 34q and electrodes 52 may be connected to each other via a conductive bonding material, for example. The conductive bonding material may be a solder material such as an alloy containing Pb, an alloy of Sn and Cu, an alloy of Sn and Sb, an alloy of Sn and Ag, or an alloy of Sn, Ag, and Cu.

The aperture diameters of the pads 34p electrically connected to the substrate connecting members 70 and the pads 34q electrically connected to the semiconductor chip 50 may be set independently of each other. According to need, the first surfaces of the pads 34p and 34q may have the previously described metal layer formed thereon, or may be subjected to an antioxidation treatment such as OSP treatment.

The interconnect layer 36 is formed on the second side of the insulating layer 31. The interconnect layer 36 includes at least one via interconnect filling a via hole 31x penetrating the insulating layer 31 and extending to the second surface of the interconnect layer 32, and also includes an interconnect pattern formed on the second surface of the insulating layer 31.

The via hole 31x is a truncated conical recess which has an opening toward the solder resist layer 37 and an end surface formed by the second surface of the interconnect layer 32, and the area of the opening is larger than the area of the bottom surface. The upper end of the via interconnect of the interconnect layer 36 filling the via hole 31x is in contact with, and electrically connected to, the second surface of the interconnect layer 32. The material of the interconnect layer 36 and the thickness of the interconnect pattern of the layer 36 may be, for example, interconnect substantially the same as those of the interconnect layer 12.

The solder resist layer 37 is formed on the second surface of the insulating layer 11 so as to cover the interconnect layer 36. The material and the thickness of the solder resist layer 37 may be, for example, substantially the same as those of the solder resist layer 13. The solder resist layer 37 has at least one opening 37x, and a part of the interconnect layer 36 is exposed in the opening 37x. The interconnect layer 36 exposed in the opening 37x forms a pad 36p. The pad 36p serves to establish an electrical connection to a mounting substrate such as a motherboard. An external connection terminal such as a solder ball may be formed on the second surface of the pad 36p. If necessary, the second surface of the pad 36p may have the previously discussed metal layer formed thereon, or may be subjected to an antioxidation treatment such as OSP treatment.

The semiconductor chip 50 is flip-chip mounted face-down on the first surface of the second substrate 30 (i.e., with the circuit surface facing the first surface of the second substrate 30). More specifically, the semiconductor chip 50 includes a chip core 51, having a semiconductor integrated circuit, and electrodes 52 as connection terminals, and the electrodes 52 of the semiconductor chip 50 are electrically connected to the pads 34q of the second substrate 30. The electrodes 52 may be, for example, gold bumps, solder bumps, or copper posts with solder at their tips.

It be noted that an electronic component incorporated in the substrate 1 with an embedded electronic component is not limited to a semiconductor chip. Instead of a semiconductor chip, passive elements such as capacitors, inductors, and resistors may be embedded. Alternatively, a CSP (chip size package) in which a semiconductor chip is provided with a redistribution layer may be embedded in the semiconductor chip. Alternatively, these components may be present in a mixture.

It is preferable to inject an underfill resin 60 into a gap between the semiconductor chip 50 and the second substrate 30 for improved reliability. The underfill resin 60 may cover part or all of the side surfaces of the semiconductor chip 50. The underfill resin 60 does not cover the upper surface of the semiconductor chip 50.

The substrate connecting members 70 are disposed between the pads 14p of the first substrate 10 and the pads 34p of the second substrate 30, and electrically connects the pads 14p and the pads 34p. The substrate connecting members 70 serve to secure a predetermined distance between the first substrate 10 and the second substrate 30. The surface area of a pad 34p that is in contact with the corresponding substrate connecting member 70 is smaller than the surface area of a pad 14p that is in contact with the corresponding substrate connecting member 70. The surface area of the pad 34p that is in contact with the corresponding substrate connecting member 70 refers to the area of the surface portion of the pad 34p that is located within, and defined by, the opening 35x. The surface area of the pad 14p that is in contact with the corresponding substrate connecting member 70 refers to the area of the surface portion of the pad 14p located within, and defined by, the opening 15x. In cross-sectional view, the width of the surface portion of the pad 14p that is in contact with the substrate connecting member 70 may be, for example, about 140 to 180 um. In cross-sectional view, the width of the surface portion of the pad 34p that is in contact with the substrate connecting member 70 may be, for example, about 110 to 150 μm.

The substrate connecting members 70 each include a first core 21, a second core 41, and a conductive member 71 covering the first core 21 and the second core 41. The first core 21 is in contact with a pad 14p. The second core 41 is located on the second substrate 30 side of the first core 21 and is in contact with a pad 34p. The first core 21 and the second core 41 are in contact with each other. The sum of the height of the first core 21 and the height of the second core 41 is greater than the distance from the surface of the second substrate 30 to the surface of the semiconductor chip 50 oriented toward the first substrate 10.

The first core 21 and the second core 41 are spherical, and the diameter of the second core 41 is less than the diameter of the first core 21. In order to reduce the width of the conductive member 71, the diameter of the second core 41 is preferably about ½ to ¼ of the diameter of the first core 21. The diameter of the first core 21 may be about 180 μm, and the diameter of the second core 41 may be about 50 μm, for example.

As the first core 21 and the second core 41, for example, a metal core made of a metal such as copper or a resin core made of a resin may be used. The conductive member 71 may be, for example, a solder material such as an alloy containing Pb, an alloy of Sn and Cu, an alloy of Sn and Sb, an alloy of Sn and Ag, or an alloy of Sn, Ag and Cu.

The substrate connecting member 70 may be arranged, for example, in a peripheral pattern around the semiconductor chip 50 in plan view. For example, when the maximum width of each substrate connecting member 70 is about 150 μm in cross section view, the pitch of the substrate connecting members 70 may be about 200 μm. In cross section view, the substrate connecting members 70 are each configured such that the width of a portion closer to the pad 34p is narrower than the width of a portion closer to the pad 14p.

The substrate connecting member 70 has an elongated shape with its longitudinal direction being along the thickness direction of the substrate 1 with an embedded electronic component. This arrangement allows the pitch between the adjacent substrate connecting members 70 to be narrow, thereby reducing the widthwise size of the substrate 1 with an embedded electronic component. For example, substrate connecting members approximately circular in cross-sectional view were used with the distance between the first substrate 10 and the second substrate 30 being the same as in FIG. 1A, the pitch between the adjacent substrate connecting members could not be narrow, causing the substrate with an embedded electronic component to become larger in the width direction. Such a problem may be avoided by using the substrate connecting members 70 having the shape illustrated in the figure. This effect is particularly prominent when an increase in the thickness of the semiconductor chip 50 causes the distance between the first substrate 10 and the second substrate 30 to be increased.

Further, the interconnect pattern of the second substrate 30 on which the semiconductor chip 50 is mounted has a higher density than that of the first substrate 10. Moreover, the surface area of a pad 34p that is in contact with the corresponding substrate connecting member 70 is smaller than the surface area of the pad 14p that is contact with the substrate connecting member 70. This arrangement improves the degree of freedom in designing a high-density interconnect pattern of the second substrate 30.

The encapsulating resin 90 fills the gap between the opposing surfaces of the first substrate 10 and the second substrate 30 to cover the substrate connecting members 70 and the semiconductor chip 50. The encapsulating resin 90 also fills the gap between the opposing surfaces of the semiconductor chip 50 and the first substrate 10. For example, an insulating resin such as a thermosetting epoxy-based resin containing a filler may be used as the encapsulating resin 90.

### Method of Making Substrate with Embedded Electronic Component

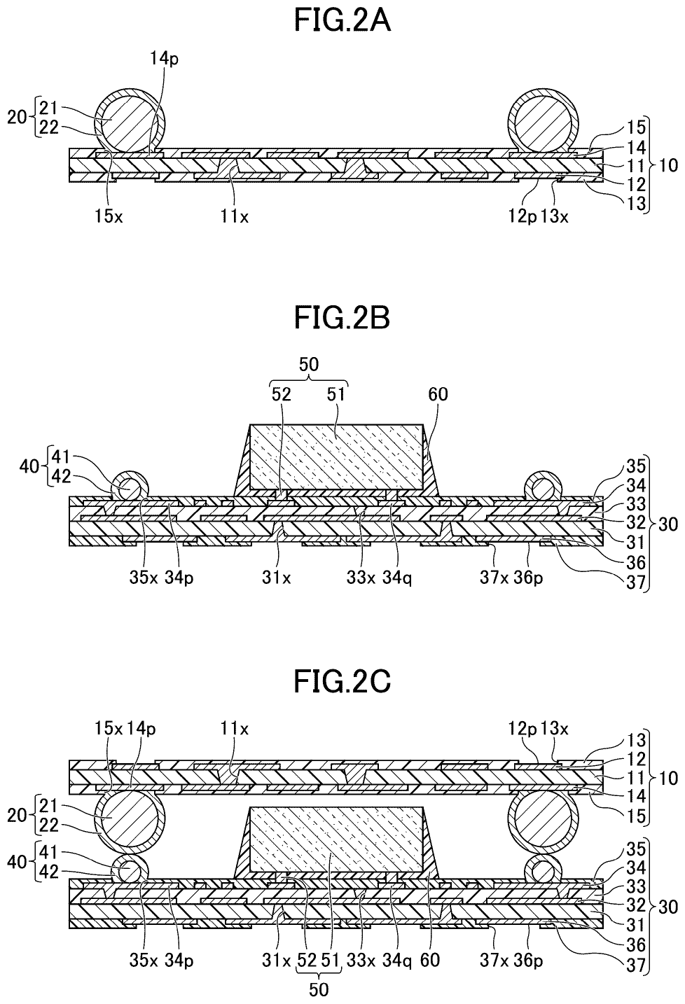

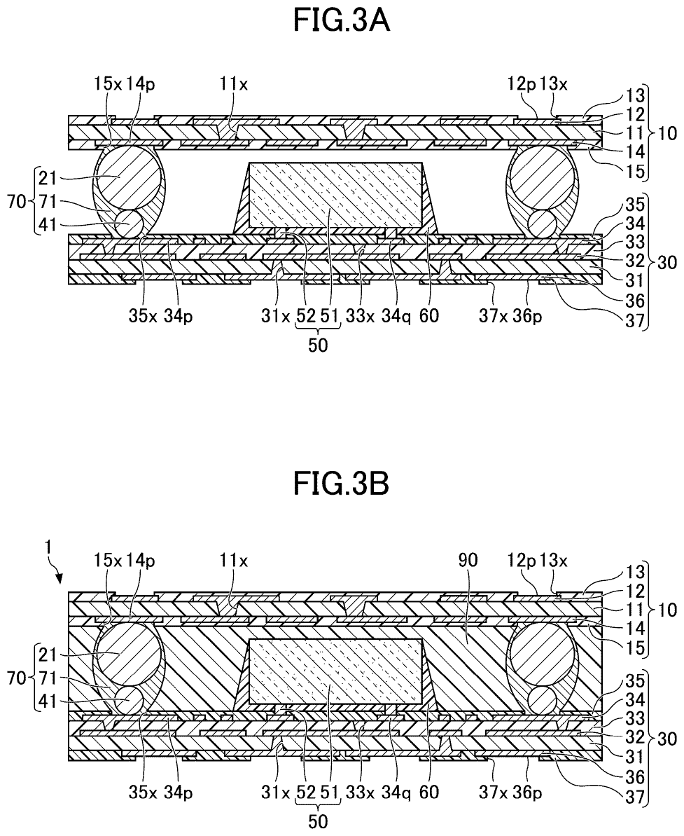

FIGS. 2A through 2C and FIGS. 3A and 3B are drawings illustrating an example of the manufacturing process of the substrate with an embedded electronic component according to the first embodiment.

First, in the step illustrated in FIG. 2A, the first substrate 10 is fabricated, and substrate connecting members 20 each including a first core 21 in contact with a pad 14p and a first conductive member 22 covering the first core 21 are mounted on the first substrate 10. Specifically, the insulating layer 11 made of a glass epoxy substrate or the like is prepared, and the interconnect layer 14 is formed on the second surface of the insulating layer 11. Then, the via holes 11x exposing the first surface of the interconnect layer 14 are formed through the insulating layer 11, and the interconnect layer 12 is formed on the first surface of the insulating layer 11. The interconnect layer 12 and the interconnect layer 14 are electrically connected across the insulating layer 11.

After the via holes 11x are formed, desmearing is preferably performed to remove resin residue adhered to the surface of the interconnect layer 14 exposed at the end of the via holes 11x. The via holes 11x may be formed by a laser processing method using, for example, a CO₂ laser. The interconnect layers 12 and 14 may be formed by one of various interconnect forming methods such as a semi-additive method or a subtractive method. For example, the interconnect layers 12 and 14 may be formed by copper plating or the like.

Subsequently, the solder resist layer 13 covering the interconnect layer 12 is formed on the first surface of the insulating layer 11, and the solder resist layer 15 covering the interconnect layer 14 is formed on the second surface of the insulating layer 11. The solder resist layer 13 may be formed by applying, for example, an insulating resin such as a photosensitive epoxy-based resin in liquid or paste form to the first surface of the insulating layer 11 by a screen printing method, a roll coating method, or a spin coating method so as to cover the interconnect layer 12.

Similarly, the solder resist layer 15 may be formed by applying, for example, an insulating resin such as a photosensitive epoxy-based resin in liquid or paste form to the second surface of the insulating layer 11 by a similar method so as to cover the interconnect layer 14. Alternatively, instead of applying the resin liquid or paste, an insulating resin such as a photosensitive epoxy-based resin film may be laminated.

By exposing and developing the coated or laminated insulating resin, the openings 13x and 15x are formed in the solder resist layers 13 and 15, respectively, thereby forming the pads 12p and 14p. This completes the first substrate 10 in its final form. The openings 13x and 15x may be formed by laser processing or blast processing. The plane shapes of the openings 13x and 15x may be, for example, circular. The diameters of the openings 13x and 15x may be determined as appropriate according to the object that is to be connected.

The substrate connecting members 20 are then placed on the surface of the pads 14p exposed in the openings 15x of the solder resist layer 15 of the first substrate 10. Each substrate connecting member 20 may be a cored solder ball including the spherical first core 21 and the first conductive member 22 covering the outer surface of the first core 21. Heating to a predetermined temperature melts the surface of the first conductive member 22 of the substrate connecting member 20, which is then solidified to be bonded to the pad 14p. The substrate connecting members 20 may be arranged in a peripheral pattern, for example.

Next, in the step illustrated in FIG. 2B, the second substrate 30 is fabricated, and substrate connecting members 40 each including a second core 41 in contact with a pad 34p and a second conductive member 42 covering the second core 41 are mounted on the second substrate 30. The semiconductor chip 50 is also mounted on the pads 34q of the second substrate 30. The second substrate 30 may be manufactured, for example, by repeating the steps of making the first substrate 10 as appropriate. The substrate connecting members 40 may be mounted in the same manner as the substrate connecting members 20.

The semiconductor chip 50 is mounted on the second substrate 30 such that t the electrodes 52 provided on the lower surface of the chip core 51 are joined to the pads 34q. Specifically, a conductive bonding material such as solder paste is applied to the pads 34q of the second substrate 30. After the semiconductor chip 50 is prepared, the back surface of the semiconductor chip 50, for example, is mounted on the lower surface of a pickup jig. The pickup jig with the semiconductor chip 50 mounted on the lower surface is moved to a position directly above the second substrate 30, and the electrodes 52 of the semiconductor chip 50 are aligned with the conductive bonding materials. The semiconductor chip 50 is then placed on the second substrate 30. After the pickup jig is removed from the semiconductor chip 50, the conductive bonding material is heated and melted by reflow soldering, and then solidified. With this arrangement, the electrodes 52 of the semiconductor chip 50 are electrically connected to the pads 34q of the second substrate 30 via the conductive bonding material. After that, the underfill resin 60 preferably fills the gap between the semiconductor chip 50 and the second substrate 30 for improved reliability.

In the step illustrated in FIG. 2C, the first substrate 10 on which the substrate connecting members 20 are mounted in the step illustrated in FIG. 2A is prepared with the second substrate 30 on which the substrate connecting members 40 and the semiconductor chip 50 are mounted in the step illustrated in FIG. 2B. The first substrate 10 is stacked on the second substrate 30 such that the substrate connecting members 20 are brought in contact with the respective substrate connecting members 40.

Specifically, a first mold and a second mold positioned above the first mold at a predetermined interval are prepared. Then, the second substrate 30 is held on the upper side of the first mold, and the first substrate 10 is held on the lower side of the second mold. The second mold is lowered toward the first mold until the substrate connecting members 20 mounted on the first substrate 10 contact the respective substrate connecting members 40 mounted on the second substrate 30, which results in the first substrate 10 being stacked on the second substrate 30. As illustrated in the drawing, the total height of the substrate connecting members 20 and the substrate connecting members 40 is greater than the distance from the surface of the second substrate 30 to the surface of the semiconductor chip 50 on the side toward the first substrate 10.

In the step illustrated in FIG. 3A, while heating the first substrate 10 and the second substrate 30, the first substrate 10 is moved toward the second substrate 30 until the first cores 21 and the second cores 41 come into contact with each other, and the first conductive members 22 and the second conductive members 42 are melted to form consolidated conductive members 71. As illustrated in the figure, the total height of the first core 21 and the second core 41 is greater than the distance from the surface of the second substrate 30 to the surface of the semiconductor chip 50 oriented toward the first substrate 10.

Specifically, for example, while heating the first mold and the second mold by a heater to melt the first conductive members 22 and the second conductive members 42, the second mold is lowered toward the first mold until the first cores 21 and the second cores 41 come into contact with each other, and the first substrate 10 is pressed toward the second substrate 30. With this arrangement, heat from the second mold is transmitted to the substrate connecting members 20 through the first substrate 10, and heat from the first mold is transmitted to the substrate connecting members 40 through the second substrate 30, so that the first conductive members 22 and the second conductive members 42 are melted to form consolidated conductive members 71. Each of the conductive members 71 covers the first core 21 and the second core 41, and is in contact with the pad 14p and the pad 34p. The heating temperature by the heater may be higher than the temperature at which the first conductive members 22 and the second conductive members 42 melt, and may be, for example, about 250° C.

Thereafter, heating of the first and second molds is stopped to solidify the conductive members 71. As a result, the upper sides of the conductive members 71 are joined to the pads 14p of the first substrate 10, and the lower sides are joined to the pads 34p of the second substrate 30. Substantially elliptical substrate connecting members 70 in cross-sectional view are formed, and the first substrate 10 and the second 30 substrate are electrically connected via the substrate connecting members 70. Moreover, a is formed between the opposing gap surfaces of the semiconductor chip 50 and the first substrate 10. In cross-sectional view, each substrate connecting member 70 is narrower at a position toward the pad 34p than at a position toward the pad 14p.

Subsequently, in the step illustrated in FIG. 3B, the encapsulating resin 90 is formed to fill the gap between the first substrate 10 and the second substrate 30 and cover the semiconductor chip 50. As the encapsulating resin for 90, example, an insulating resin such as a thermosetting epoxy-based resin containing a filler may be used. The encapsulating resin 90 may be formed by, for example, a transfer molding method using a sealing mold.

Through the above-described steps, the substrate 1 with an embedded electronic component is effectively constructed. If necessary, external connection terminals such as solder balls may be formed on the pads 36p.

### Variation of the First Embodiment

A variation of the first embodiment is directed to an example in which the pads of the second substrate 30 are larger than the pads of the first substrate 10. In connection with the variation of the first embodiment, the description of the same components as those of the already described embodiment may sometimes be omitted.

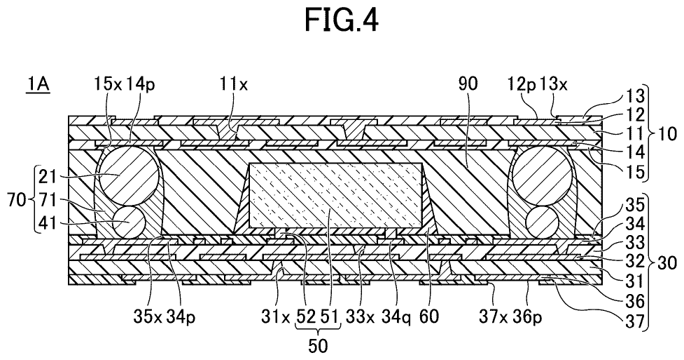

FIG. 4 is a cross-sectional view illustrating an example of a substrate with an embedded electronic component according to the variation of the first embodiment. Referring to FIG. 4, a substrate 1A with an embedded electronic component is such that the surface areas of the pads 34p that are in contact with the respective substrate connecting members 70 are larger than the surface areas of the pads 14p that are in contact with the respective substrate connecting members 70. In the cross-sectional view, the width of the surface portion of each pad 14p that is in contact with the corresponding substrate connecting member 70 may be, for example, about 110 to 150 μm. The width of the surface portion of each pad 34p that is in contact with the corresponding substrate connecting member 70 in cross-sectional view may be, for example, about 140 to 180 μm. In cross-sectional view, each substrate connecting member 70 is narrower at a position toward the first substrate 10 than at a position toward the second substrate 30. The method of manufacturing the substrate 1A with an embedded electronic component is substantially the same as that of the substrate 1 with an embedded electronic component.

Like the substrate 1 with an embedded electronic component, the substrate 1A with an embedded electronic component is such that each substrate connecting member 70 is elongated, with its longitudinal direction oriented along the thickness direction of the substrate 1A with an embedded electronic component. With this arrangement, the pitch of the adjacent substrate connecting members 70 is effectively narrowed, which enables the size reduction of the substrate 1A with an embedded electronic component in the width direction. This effect is particularly prominent when an increase in the thickness of the semiconductor chip 50 causes an increase in the distance between the first substrate 10 and the second substrate 30.

In the substrate 1A with an embedded electronic component, the substrate connecting member 70 is narrower at a position toward the first substrate 10 than at a position toward the second substrate 30. This arrangement improves the fluidity of the encapsulating resin 90 around a portion of the substrate connecting member 70 toward the pad 14p when forming the encapsulating resin 90 during the manufacturing process of the substrate 1A with an electronic component. As a result, the encapsulating resin 90 can be easily injected into the gap between the opposing surfaces of the semiconductor chip 50 and the first substrate 10. It is also possible to reduce the possibility of void formation between the opposing surfaces of the semiconductor chip 50 and the first substrate 10.

Although the preferred embodiments have been described in detail above, the disclosed technology is not to the above-described embodiments, and various modifications and substitutions may be made to the above-described embodiments without departing from the scope of the claims.

For example, the first substrate or the second substrate may be a build-up substrate or the like having a larger number of interconnect layers and insulating layers. In this case, a coreless build-up substrate or a build-up substrate with a core may be used. In addition, a lead frame may be used as the first substrate.

In addition, one of the first core 21 and the second core 41 may be a resin core and the other may be a metal core. For example, the first core 21 having a larger diameter than the second core 41 may be a resin core. This arrangement provides a greater margin for elastic deformation than when the second core 41 having a smaller diameter than the first core 21 is a resin core. Even when the first substrate 10 and/or the second substrate 30 have a non-uniform thickness, the first cores 21 are elastically deformed when the first substrate 10 and the second substrate 30 are brought close to each other, thereby effectively reducing poor between the contact substrate connecting member 20 and the substrate connecting member 40.

According to the disclosed technology, a substrate with an embedded electronic component is effectively provided that is unlikely to be enlarged in the width direction even when the thickness of the electronic component is increased.

The present disclosures non-exclusively include the subject matter set out in the following clauses.

Clause 1. A method of making a substrate with an embedded electronic component, comprising: mounting, on a first substrate having a
first a pad, first substrate connecting member including a first core in contact with the first pad and a first conductive member covering the first core; mounting, on a second substrate having a
second pad, an electronic component and a second substrate connecting member including a second core in contact with the second pad and a second conductive member covering the second core; stacking the first substrate on the second
substrate such that the first substrate connecting member and the second substrate connecting member are brought into contact with each other; and
moving the first substrate toward the second substrate while heating the first substrate and the second substrate until the first core and the second core come into contact with each other, and, in conjunction therewith, forming a consolidated conductive member made by melting and consolidating the first conductive member and the second conductive member,
wherein the first core and the second core are spherical, and a diameter of the second core is smaller than a diameter of the first core, and
wherein the consolidated conductive member covers the first core and the second core and are in contact with the first pad and the second pad.

Clause 2. The method according to clause 1, wherein a sum of a height of the first core and a height of the second core is greater than a distance from a surface of the second substrate to a surface of the electronic component that is oriented toward the first substrate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A substrate with an embedded electronic component, comprising:
a first substrate;
a second substrate on which an electronic component is mounted; and
a substrate connecting member electrically connecting a first pad of the first substrate and a second pad of the second substrate,
wherein the first substrate is disposed opposite the second substrate across the electronic component,
wherein the substrate connecting member includes:
a first core in contact with the first pad;
a second core in contact with the first core and the second pad; and
a conductive member covering the first core and the second core, and in contact with the first pad and the second pad, and
wherein the first core and the second core are spherical, and a diameter of the second core is smaller than a diameter of the first core.

2. The substrate with an embedded electronic component according to claim 1, wherein the first substrate has a first interconnect pattern on a same plane as the first pad,
wherein the second substrate has a second interconnect pattern on a same plane as the second pad, and
wherein the second interconnect pattern has a higher density than the first interconnect pattern.

3. The substrate with an embedded electronic component according to claim 1, wherein a surface area of the second pad that is in contact with the substrate connecting member is smaller than a surface area of the first pad that is in contact with the substrate connecting member.

4. The substrate with an embedded electronic component according to claim 1, wherein the first core, among the first core and the second core, is a resin core.

5. The substrate with an embedded electronic component according to claim 1, wherein a surface area of the second pad that is in contact with the substrate connecting member is larger than a surface area of the first pad that is in contact with the substrate connecting member.

6. The substrate with an embedded electronic component according to claim 1, wherein a sum of a height of the first core and a height of the second core is greater than a distance from a surface of the second substrate to a surface of the electronic component that is oriented toward the first substrate.

7. The substrate with an embedded electronic component according to claim 1, further comprising an encapsulating resin filling a gap between the first substrate and the second substrate to cover the electronic component and the substrate connecting member.
